(19) United States
(12) Patent Application Publication
(10) Pub. No.: US 2012/0040166 A1
(43) Pub. Date: Feb. 16, 2012

(54) Composite Material, Method of Manufacturing and Device for Moldable Calibration

(76) Inventors: Gabreal Livschits, San Francisco, CA (US); Gennadiy Flider, San Francisco, CA (US)

(21) Appl. No.: 13/108,597

(22) Filed: May 16, 2011

Related U.S. Application Data
(60) Provisional application No. 61/334,578, filed on May 14, 2010.

(51) Int. Cl. B32B 5/16; B32B 15/02; H01L 23/48; B32B 9/00; B32B 5/18; B29C 67/00; B32B 5/14

(52) U.S. Cl. 428/221; 264/239; 425/470; 257/734; 257/E23.01

(57) ABSTRACT

Composite materials and methods and systems for their manufacture are provided. According to one aspect, a composite material includes a collection of molded together multilayer capsules, each capsule originally formed of a core and shell. The shell, after a plastic deformation process, forms a pseudo-porous structure, with pores locations containing the capsule cores. The cores are made of a material, e.g., synthetic diamond, which is harder than the external shell, which can be formed of, e.g., a ductile metal such as copper. The composite material has high thermal and/or electrical conductivity and/or dissipation.

### REFERENCE TO RELATED APPLICATION

This application claims the priority benefit under 35 U.S.C. §119(e) of U.S. Provisional Application No. 61/334,578, filed May 14, 2010, the entire disclosure of which is incorporated herein by reference.

### TECHNICAL FIELD

The present invention relates to composite materials with various pre-defined properties, including high thermal conductivity or dissipation, and/or high electrical conductivity or dissipation.

### DESCRIPTION OF THE RELATED TECHNOLOGY

Due to the high-energy per volume utilized by various high-energy electronic devices, such as laser diodes, materials having high heat resistance and conductivity are typically employed in these devices to withstand the high energies and maintain a desired operating temperature. Example of such materials include:
copper-tungsten;
copper-molybdenum;
aluminum silicon carbide;
aluminum-silicone;
aluminum nitride;
aynthetic diamond;
synthetic single crystal diamond; and
diamond copper composite.

The diamond copper composite is designated as DMCH (Diamond Metal Composite for Heat Sink) and produced by SUMITOMO ELECTRIC USA, INC. U.S. Pat. No. 6,270,848, issued Aug. 7, 2001, describes such a diamond copper composite. This composite's thermal resistance and thermal conductivity is believed to be three times that of ordinary composites.

Some modern electronic devices, such as electron optical systems, however, require much higher performance characteristics, e.g., thermal resistance and thermal conductivity 4-5 times higher than that of ordinary composites.

### SUMMARY

According to some implementations, a composite material having high thermal conductivity or dissipation, and/or high electrical conductivity or dissipation is provided. In some embodiments, the composite material has a three-dimensional structure in which adjoining elements have differing physical properties. The three-dimensional structure can include a collection of multilayered capsules accommodated in a mold. The mold has a three-dimensional pseudo-porous form with pores that contain the capsules. The cores of the capsules are made from a material which is harder than the external layers of the material.

According to some other implementations, a method and a system is provided for producing a pseudo sponge or pseudo porous composite material. A collection of nano-capsules are provided bound together into a three-dimensional structure. The nano-capsules are subjected to a plastic calibrating volume deformation in a cold-drawn state for nano-capsule ductile shell material production.

According to yet some other implementations, a method and system for producing a composite material formed from a collection of molded spherical multi-layered capsules is provided. The method includes, in two successive steps, first contacting capsule spheres with an external spherical surface, the contact being point contact; and second, placing the blank after the first step in a three-dimensional enclosed volume geometrically equivalent to the design form of the object, and subjecting the blank in this volume to high pressure spreading along all the axes and coordinates of the volume wherein the level of specific pressure brings the capsules' plastic shell material to a cold-drawn state and transforms the contact between the spheres from point contact into full contact along mating faces.

According to some other implementations, a method and system for producing a composite material having simultaneously thermally conductive and electrically conductive properties, or dielectric and electrically conductive properties, is provided. The method and system include the production of capsule spherical cores, coating the capsules with material, at least one external shell, placing a pre-determined number of capsules into a mold with linear dimensions of the matrix being a multiple of the dimensions of the capsule, applying high pressure to the capsule until cold-drawn and fluidity effect appears in the metal of capsule shells, and holding and calibrating the size dimensions of an object made from the composite material.

According to yet some other implementations, a device for forming a composite material from a collection of multi-layered capsules is provided. The device includes a matrix replicating the shape of the final object to be made from the composite material, the matrix having the size a multiple of the size of the capsules before the start of the process of plastic deformation and punch, having a cross-section geometrically correlated with the cross section of the matrix, the geometric correlation changing as a function of the properties of the ductile material of capsule shells.

The skilled artisan will understand that various implementations provide a solution for one or more of the following technical difficulties:
providing a structure of a multi-layer (multi-level) capsule;
providing a geometric form for the multi-layer (multi-level) capsule—e.g., a sphere;
providing for the alternation of layers (levels) in the spherical capsule;
providing for an order and geometry for the spherical capsules in the resulting object's three-dimensional structure;
providing for operational procedures involved in manufacturing the object;
providing for inclusion of the operation to calibrate the geometrical form of the object, after a first molding stage;
providing for performing a calibration operation in a three-dimensional coordinate system;
providing for performing a calibration operation while the external layer (shell) of the capsule is in a state close or equivalent to the state of cold-drawn metal;
providing for removing, during calibration, all of the object's three-dimensional spaces unfilled with electrically conductive material;
providing for forming, in the object's three-dimensional space, a pseudo porous structure. The role of separating points in the structure is taken by less ductile materials from among those which are used in the capsule's composite;
providing for the use of the object's pseudo porous structure to dissipate heat and current around the entire volume of the object;
providing for the use of the object's pseudo porous structure to absorb (adsorb) excess energy occurring during peaks of object's pulse operation mode in an electronic device;
providing for the use of the cold-drawn state to alleviate internal stress in the material and to calibrate the sizes simultaneously in three coordinates;
providing for combining materials in the hierarchy of capsule's sphere-shaped shells so that each subsequent layer is less hard and more ductile; and
providing for combining materials in the hierarchy of the capsule's sphere-shaped core and shells so that the core is out of a material which is the hardest of all the materials used to create the capsule.

Various processes for manufacturing diamond nano-powders with substantially identical granule sizes are disclosed herein.

Various processes for coating diamond nano-powders with copper or other plastic metal are disclosed herein.

Various implementations have an effect on and may be used in a number of technological areas in different industries, including for high-energy electronic devices such as lasers, including laser diodes.

Various implementations increase the level of a material's effectiveness as it concerns heat conduction and dissipation (e.g., the rate at which heat is diverted from heat sources and the reliability of the process of selecting and using heat in cases of long-term operation of the object at which the temperature fluctuation level is stabilized); and increase a material's effectiveness in terms of electrical conductivity and current dissipation (e.g., eliminate current loss while it passes through the structure and increase the level of reliability of the current passage and dissipation over a long period of operation).

Various implementations apply the following technical solutions to increase heat conduction and dissipation and/or to increase electrical conductivity and current dissipation:
decrease the diameter of two-layer capsules, for example, to the minimum allowed by a manufacturing process (the smaller, the more effective in some cases); and
calibrating the geometric shape of the structure by plastically deforming capsule shells in the cold-drawn mode, thereby decreasing the volume of the cavities in the empty spaces between the capsules, lowering the electric and thermal resistance, improving mechanical characteristics of the structure and alleviating internal stresses in the three-dimensional hierarchy of the structure.

Various implementations provide a highly thermal-conductive composite material with high electrical conductivity characteristics and able to: absorb and dissipate significant amounts of energy, particularly over short periods of time; absorb and transfer significant amounts of energy at a distance possessing a high mechanical strength, and with high reliability, while preserving precise geometric shapes while under the impact of high concentrations of temperatures, energy and other types of damaging and extreme exposure.

Some implementations may provide one or more of the following:
a composite material with a developed three-dimensional structure composed of a collection of substantially identical multi-level spherical shells covering spherical cores;
cores with shells (capsules) are attached to each other in the process of a series of successive technological operations with a contact type substantially equivalent for all of the capsules of the structure;
a composite material, by virtue of its structure, having super thermal conductivity and super electricity conductivity properties;
a composite material having high mechanical strength, which is not prone to the occurrence of internal mechanical and temperature stresses and therefore to internal deformations resulting from them; and
a composite material capable of withstanding high pressure and under this high pressure, for at least some of the components, to enter the cold-drawn metal state making it possible to calibrate the structure's three-dimensional geometrical shape and to ensure highly accurate geometrical dimensions of the structure with a high level of recurrence.

Materials according to some implementations provide a composite material which serves as a conductor of electrical current and as an effective heat conductor with a developed three-dimensional electrically conductive structure, with uniformly distributed nodes (microspheres) which are the points of high thermal conductivity without conducting electrical current (e.g., produced from materials with high heat-conductivity, for example, diamonds with thermal conductivity coefficient of 1200, and which does not conduct electrical current).

In some implementations, the material resembles a three-dimensional grid, with diamond spheres in its nodes, diamonds being the an exceptional thermal conductor, the diamonds being separated in the three-dimensional space of the structure from each other with copper shells, which are excellent conductors and thermal conductors.

Therefore, for electrical current flow (which is desirable for pulsed current applications), the composite structure may be arranged as a pseudo-sponge or pseudo-porous volume and dielectric spherical spaces are placed around the entire volume of the electrically conductive material and are comparable in size with the size of the current-conducting space.

In some implementations, the materials are amenable to sufficiently rapid and uniform dissipation of current on the one hand, and to rapid, effective and uniform dissipation of heat on the other hand within the same material volume.

Ductile materials may be used as the shell material, copper or silver, for example, which have the high electrical conductivity coefficients. At high pressures in an enclosed volume, the above metals can be brought to cold-drawn state. If pressure is applied in an enclosed three dimensional volume, the type and the form of interaction between the capsules in the structure change, helping make objects with the required technical and technological properties, which is difficult to obtain through the use of conventional technologies.

In some implementations, a method is provided for producing pseudo-sponge or pseudo-porous composite material in the form of a collection of nano-capsules bound to each other into a three-dimensional structure and subjected to volumetric plastic deformation in the cold-drawn mode for the nano-capsule shell material.

### BRIEF DESCRIPTION OF THE DRAWINGS

The invention will be better understood from the Detailed Description and from the appended drawings, which are meant to illustrate and not to limit the invention. The Figures are not necessarily drawn to scale, nor are the relative sizes of parts within the Figures necessary in proportional to one another.

FIG. 1 illustrates an example of a composite material structure, shown in isometric projection;

FIG. 2 illustrates an example of a two-component capsule, shown in a perspective, cut-away view;

FIGS. 3A and 3B illustrate an example of capsule components presented separately, shown in perspective views;

FIG. 3A illustrates an example of a capsule core, shown in a perspective view;

FIG. 3B illustrates an example of capsule shell, shown in a perspective, cut-away view;

FIG. 4 illustrates an example of several layers of composite materials, shown in isometric projection;

FIG. 5 illustrates an example of several layers of composite materials showing geometric correlation between the layers and components within limits of one layer;

FIG. 6 illustrates an example of a cross-section of a mold used to calibrate a composite material blank;

FIGS. 7A-7C illustrates an examples of steps involved in calibrating a composite material in the mold, with FIG. 7A illustrating dimensional ratios between mold walls and capsules; FIG. 7B illustrating conceptual ratios between the total sizes of the capsules in one layer and between the mold walls; and FIG. 7C illustrating geometry ratios between capsules within one layer of composite material after calibration; and

FIGS. 8-10 illustrate examples of models of the structure of composite materials according to some implementations of the invention.

### DETAILED DESCRIPTION

Initial experiments with a new generation of powerful semiconductor lasers have shown that a significant measure of performance, durability and reliability of the instruments is ensuring a stable operation temperature. In high-power, external-cavity optically-pumped semiconductor lasers this measure is even more significant, as it is with many power electronics.

Some implementations of the invention provide a composite complex multi-component material, produced on the basis of modified diamond nano-powders encapsulated in a shell of copper or other metal, ensuring a stable operating temperature for the electronics. The material may also solve thermodynamic issues in many other areas of modern technology, particularly where temperature stability is desired.

In some implementations, the material includes a metal ceramic alloy in the form of nanospheres made of artificial diamonds encased in copper, aluminum or other plastic or deformable metal compressed in a mold (note that it occurs with an increase in temperature, but using appropriate pressure and the principle of extremely strong bonds between particles under one nanometer in size).

The use of parts formed of the proposed material may yield more stable laser diode operation results as well as more stable operation of other high-energy electronic systems.

In some implementations, the material may possess one or more of the following properties:
be electrically conductive and dissipative
be thermally conductive and thermally dissipative;
be electrically conductive and thermally dissipative; and
be thermally conductive and electrically dissipative.

The capsule components based on spherical multi-layer components may be within the nanometer size range.

The following may be used as a substrate for the heterostructure of laser diodes or other electronics:
copper plates;
ceramic plates;
ceramics (e.g., aluminum nitride).

Various materials have been used for diodes and electronics employed for other purposes, but generally, the absence of effective composite materials has slowed progress related to developing new, more powerful semi-conductor lasers (or laser diodes) and high-energy electronic systems. Since more powerful laser diodes are expected to be used in the new generation of TV's, the materials disclosed herein may also have application to those devices. For the new generations of audio and video systems, the calculated optical power of laser diodes is 4 watts for CW mode and 7 watts for operation in the radiofrequency band, at peak pulse, if the multi-layer optical disk concept is used. Experiments related to creating these types of powerful laser diodes have showed that in absence of a composite material with boosted heat transfer parameters, these types of powerful diodes may be not be operational.

Nano-composite materials according to some implementations of the invention are capable of yielding levels of performance with thermal resistance and thermal conductivity being 4-5 times higher than that of ordinary composites. Benefits arising from the use of the composite materials can include options for the evolution and development of the following applications of this composite in various areas of application, including for laser diodes and high energy electronics.

The composition of the nano-composite material, according to some implementations, can include:

| Capsule core | Capsule shell |
|---|---|
| ceramics; | copper; silver; aluminum; nickel; |
| tungsten; | copper; silver; nickel; aluminum; |
| iron; | aluminum; copper; |
| beryllium; | aluminum; |
| magnesium; | aluminum; |
| silicon; | copper; silver; gold; |
| zirconium; | aluminum; |
| diamond; | copper; silver; gold; |
| glass-ceramic materials; | copper; silver; gold; |
| hard alloy; | copper; aluminum; cobalt; molybdenum |

Examples of composite material applications as a component part include:
Beryllium-aluminum; and
Magnesium-aluminum.

These composites can be used to manufacture bases for PC memory hard disks. Technical characteristics of these disks, e.g., low specific mass of construction material, are capable of operating at more than 20000 RPM.

The materials may open up new opportunities in the following areas:
creating hybrid disks;
coating processes in microelectronics;
creating activating additives for fuel; and
to manufacture vital parts.

In some implementations, one or more of the following advantages may be realized:
the composite material may have only two components—diamond spheres (grains) and copper shells for them, whereas the components, as copper shells are created by coating diamond spheres are highly homogeneous since coating thickness is substantially equal for substantially all diamond spheres;
the composite material may have a high heat dissipation effect;
the composite material may have a high current dissipation effect;
the composite material's electrical resistance may be equivalent to the electrical resistance of copper;
the composite material may be formed and calibrated by employing the cold-drawn effect of copper (or any other ductile metal);
the composite material may have a high mechanical strength due to calibration by generating cold drawn state;
the composite material may have a high electrical conductivity level due to calibration by method of generating cold-drawn state;
the composite material may have more precise dimensions due to calibration by method of generating cold-drawn state; and
the composite material may have a very high thermal conductivity level due to the very small capsule size (nanometers) and due to calibration by method of generating cold-drawn state.

The production of composite materials according to some implementations can involve several successive stages. These stages may vary depending on the type of production to be used and by the method used to prepare material components to be used later to prepare the composite. As an example, the various stages can include:
1. Diamond powder production with the required grain sizes.
2. Copper coating diamond nano-powder.
3. First molding in the mold. The size of the nano-composite supports may be about lx 2 mm; about 1×3 mm; and about 2×3 mm. The thickness may be approximately about 200 micron or larger.
4. Calibration. Capsule shells are plastically deformed in a mold to form a porous structure of a desired shape, with the capsule cores occupying the pore volumes.

In some implementations, the composite materials, after completing all of the operations involved in producing it, acquires a finished geometric structure, a prism, for example, which can be considered to be a current-conducting object with dielectric spheres, produced from synthetic diamonds, substantially uniformly distributed inside it.

The cross-section of this conductor can be large, and, due to the developed three-dimensional structure, this type of conductor has low electrical resistance. Since the electrically conductive structure volume includes diamond granules (spheres), which are not current conductors, the current envelopes these areas in the structure's body and passes exclusively into the current-conducting volume (e.g., the mold in which the granules are embedded). This current dissipation or distribution path around the relatively large cross-section of the granules can significantly decrease losses and increase the current passage rate.

If it is needed to dissipate heat, the pseudo-porous structure exists in the shape of nodes of a specific grid. Diamond spheres are located in the nodes. The spheres' resistance is 4-5 times lower than for the structure as a whole, resulting in heat gravitating toward the grid nodes, which in turn ensures a fast outward movement (dissipation) of heat from its source.

Both scenarios therefore create the phenomenon of spotted three-dimensional distribution of areas with different specific thermal conductivity and current conductivity coefficients.

Furthermore, nanometer-sized capsules and the final plastic deformation in the cold-drawn state help significantly to reduce voids between capsules, which in turn increases the effectiveness of selection, as well as the effectiveness of heat and current pulse dissipation.

Calculations show that the expected heat dissipation effect is about 4-5 times that of typical materials.

A semi-conductor laser (laser diode) packaging and body is an example of composite material use. For example, the material may be employed in a laser diode with multi-modal emissions and output optical power of about 1 W. One Ampere or more of current can be supplied to obtain an output power of about 1 W in order to control the diode. The resulting voltage would be at least about 2 V, taking into account internal resistance of the laser diode itself and the electronic control system. Thus, the total consumed power may be about 2 W, with real output power of about 1 W.

A power loss coefficient of 50% is among the best known results currently. The above indicates that the least loaded laser diode with multi-modal emissions (beam cross section is 300 micron×1-3 microns) requires about 1 W of energy to be dissipated. This type of diode requires a standard body designated SOT-148 with installation flange diameter of 9 mm. The composite material dissipates the large specific quantity of heat. The material diverts heat generated by converting 1 W of power into heat, from the laser diode's hetero-structure not larger than a standard integrated circuit semi-conductor crystal.

Nominal operating temperatures in the area of the heterostructure desirably do not exceed about 25-27 degrees C. In order to transfer this amount of heat, the heterostucture may be welded to the composite support which dissipates heat onto the diode body, which in turn gives off the generated heat into a cooling system (thermal electric cooler).

It will be appreciated that the more effective the material, the more effective the laser diode operation, including stability, durability and power output.

It will also be appreciated that heat dissipation concerns become even more urgent if heat needs to be diverted away from a single-mode diode, since in these types of diodes, the beam cross-section is a circumference about 0.6 micron in diameter. In this case, the concentration of energy is even higher whereas the heat diversion and dissipation function becomes even more relevant.

In light of the fact that just for the needs of various types of video systems, optical memory systems, PC optical memory drives and other similar objects, require laser light sources, in different parts of the spectrum, the annual demand for laser diodes is large. Primary, the optical capacity of the used laser diodes is approximately 80 mW. However, they all operate in the red spectrum range and are uni-modal, making the application of a new and effective composite, such as according to some implementations of the invention, extremely relevant.

Reference will now be made to the Figures, in which like numbers reference to like parts throughout.

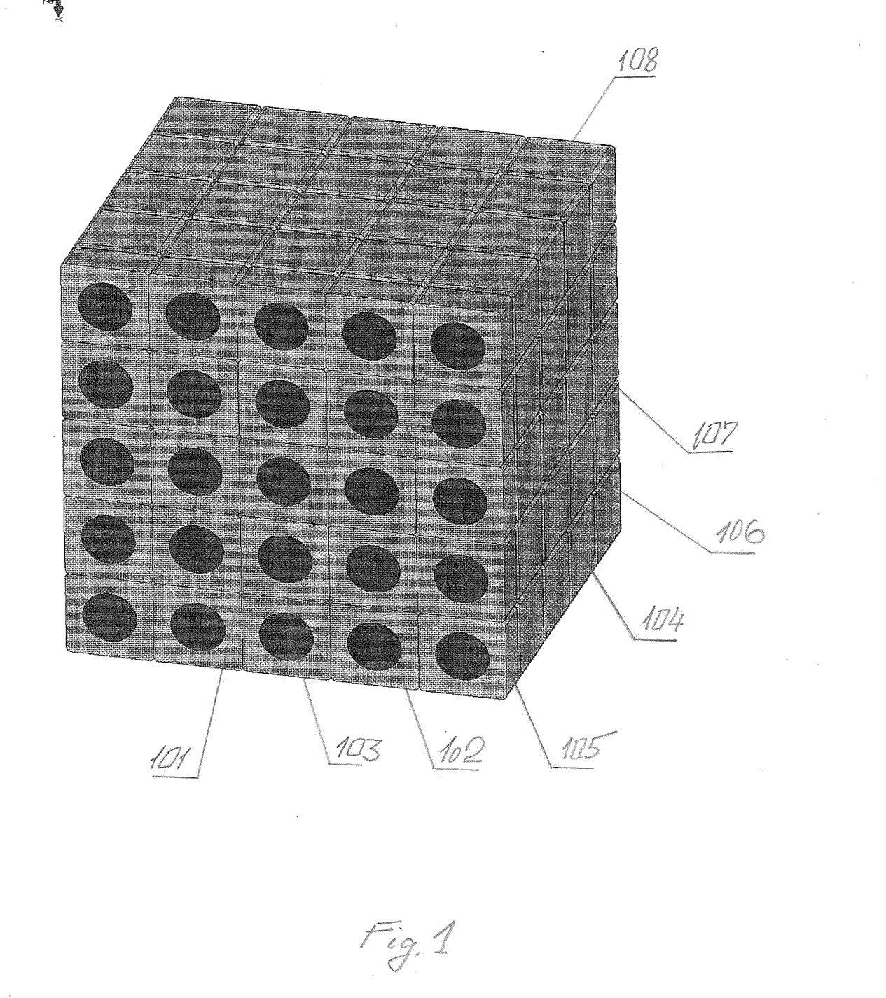

FIG. 1 shows a view of a bar of composite materials after completion of the calibration process. The following reference numerals identify the following parts:
101—composite material bar;
102—capsule shell after it was plastically deformed during calibration;
103—capsule core, not deformed in the process of calibration and creation of cold-drawn effect and state for the capsule shell material;
104—the shape of capsule's external surface after calibration;
105—section of a layer of composite material cut across the centers of spherical cores;
106—capsule surfaces which are contacted after calibration;
107—capsule ribs after calibration; and
108—nodes at capsule peaks after calibration.

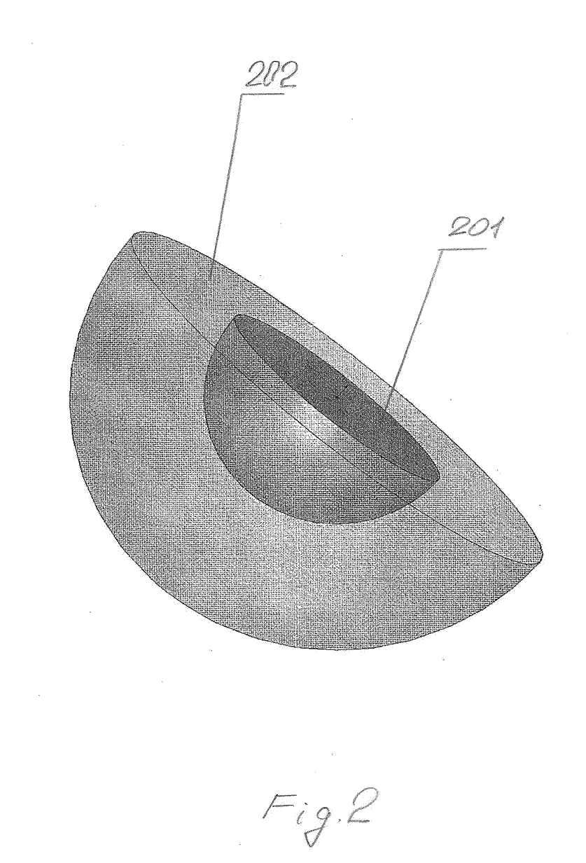

FIG. 2 shows an axial cross-section of a capsule. The following reference numerals identify the following parts:
201—capsule core made out of high hardness material, the material not conducting electricity, but conducting heat; the core size may, depending on how the capsule is used, change within a range of about 0.001-0.01 mm; in special cases, core size may change within the range of about 0.0001-0.0005 mm, the core may be produced from diamonds, as well as aluminum nitride or titanium-based ceramic materials; and
202—shell of a capsule made from highly ductile metal, for example, from copper, silver, or gold; the three metals have high electricity conducting capabilities; shell's inner diameter is determined by the core sphere diameter; the external diameter's size is determined by the thickness of the shell. In some implementations, to facilitate the calibration, the shell thickness is bigger or equal to the core's diameter. In some implementations, the capsule sphere's external diameter equals two diameters of its core.

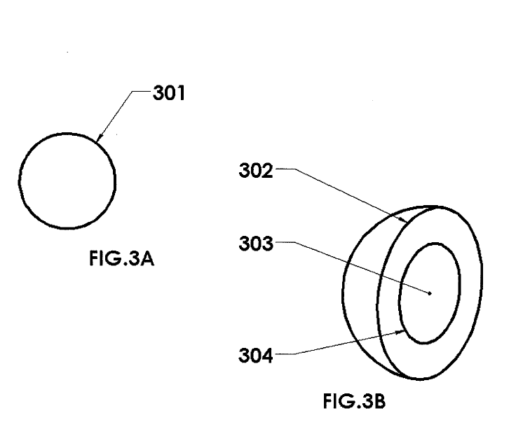

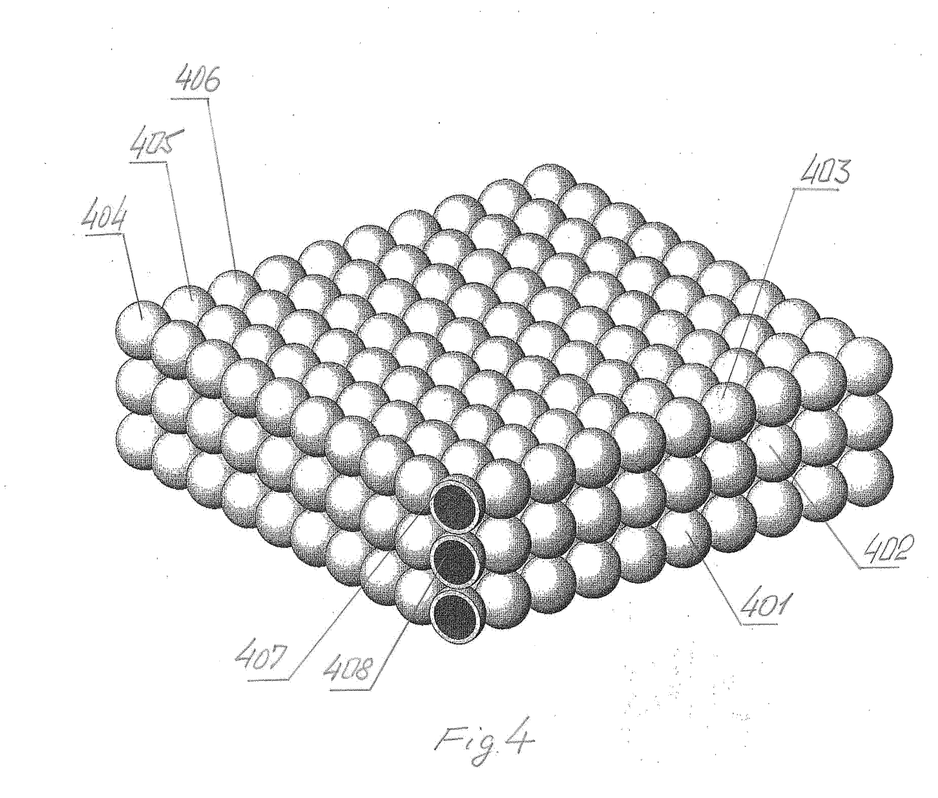

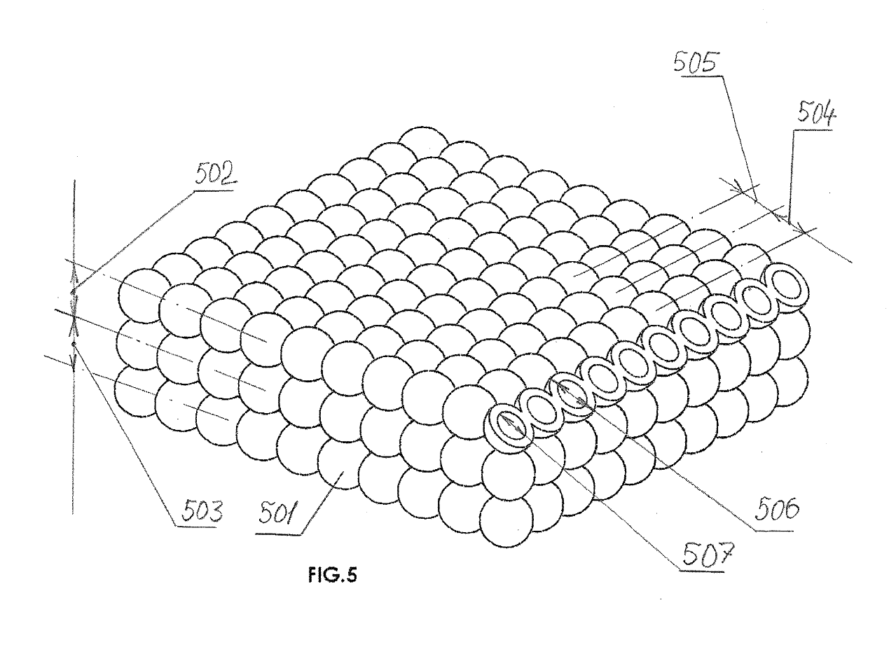

FIGS. 3A and 3B show three-dimensional models of capsule components before calibration. The following reference numerals identify the following parts:
301—FIG. 3A—capsule's spherical core model. Modern technologies make it possible to obtain microscopic particles geometrically shaped as a sphere;
302—FIG. 3B—external capsule shell diameter;
303—internal diameter of capsule shell's spherical cavity where the spherical core is located; and
304—internal capsule shell diameter.

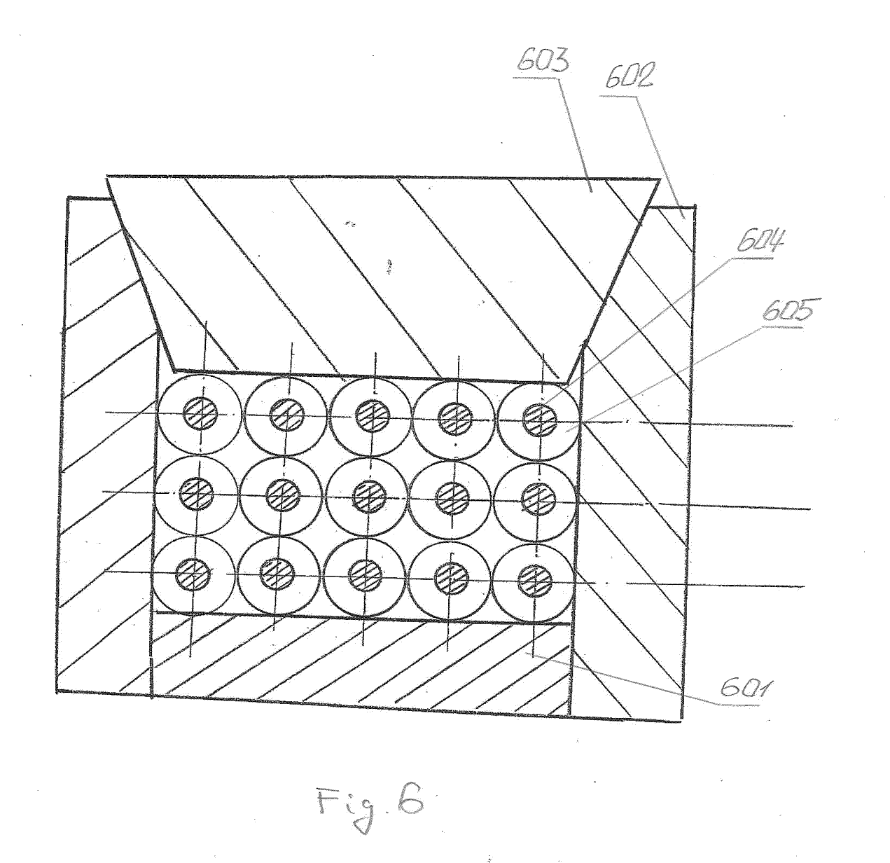

FIG. 4 shows a three-dimensional model of a plate made out of a composite material containing three capsule layers, after the first stage of formation in the compression mold, without high-pressure application. The following reference numerals identify the following parts:
401—one of the many capsules of the first layer;
402—one of the many capsules of the second layer;
403—one of the many capsules of the third layer;
404—first row out of the multitude of the capsules of the top layer;
405—second row out of the multitude of the capsules of the top layer;
406—third row out of the multitude of the capsules of the top layer;
407—capsule shell cross-section; and
408—capsule core cross-section.

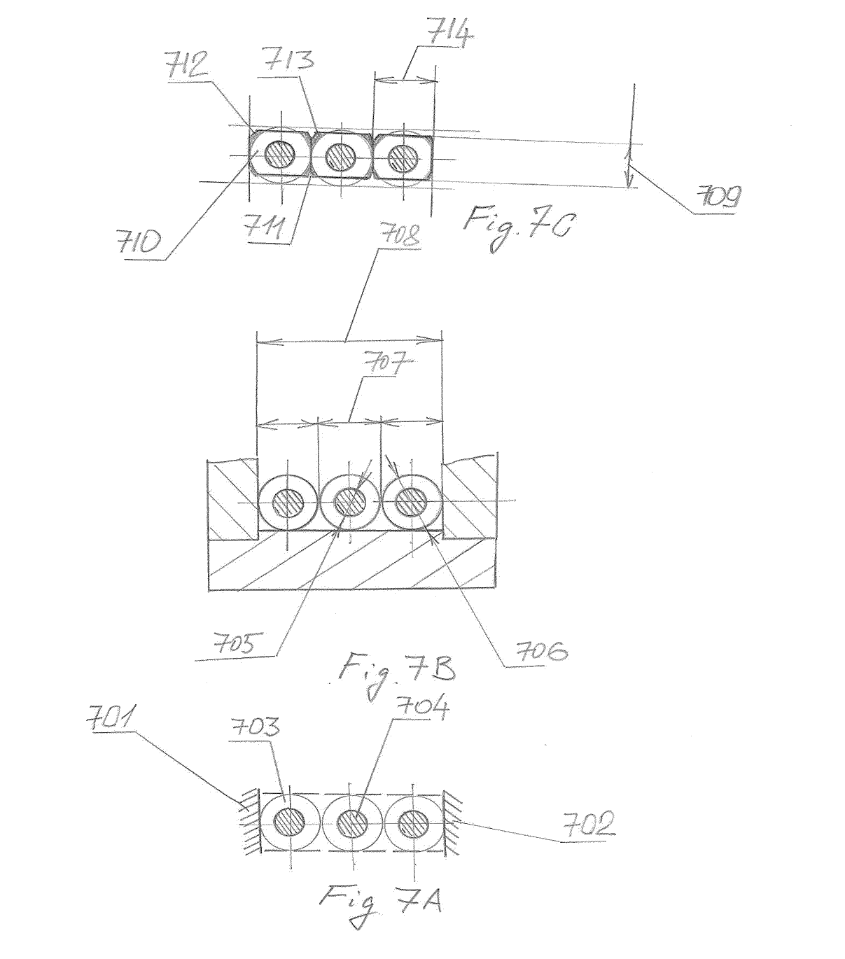

FIG. 5 shows a schematic of the geometric proportions in a three-dimensional model of the composite material plate, including three layers of capsules, after completion of the first molding in the mold and before calibration. The following reference numerals identify the following parts:
501—lower layer of the plate model;
502—distance between the second and the third layers of the three dimensional plate model, about equal to the capsule's external diameter;
503—distance between the first and the second layers of the three-dimensional model of the plate, about equal to the capsule's external diameter;
504—distance between the rows of capsules within the limits of the third layer of the three-dimensional model of the plate, between the outermost row of capsules and rows following it; distance is about equal to the external diameter of the capsule;
505—distance between the rows of capsules within the limits of one layer; the distance is about equal to the capsule's external diameter;
506—external diameter of the capsule, about equal to the external diameter of the capsule's shell; and
507—internal diameter of the capsule's shell, about equal to the external diameter of the capsule's core.

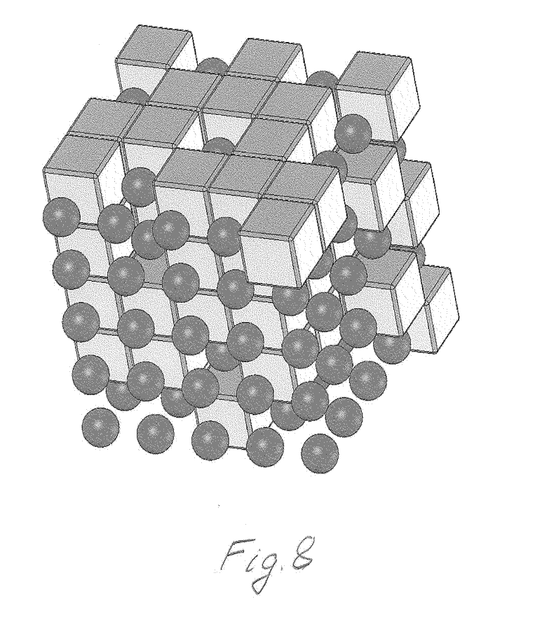

FIG. 6 shows a vertical cross-section of the calibration mold used in the calibration process. The following reference numerals identify the following parts:
601—base of the compression mold made from tool steel whose surface is hardened by gas thermal treatment, for example—by nitride hardening, for example, after preliminary structural thermal refining and normalization;
602—side walls of the mold produced in accordance with the principles of producing base 601; the distance between two adjacent side walls is equal to the exact number of capsules in one layer of the composite material plate multiplied by the external diameter of the capsule;
603—calibrating element of the mold made from the material substantially identical to that of base 601;
604—capsule core; and
605—capsule shell.

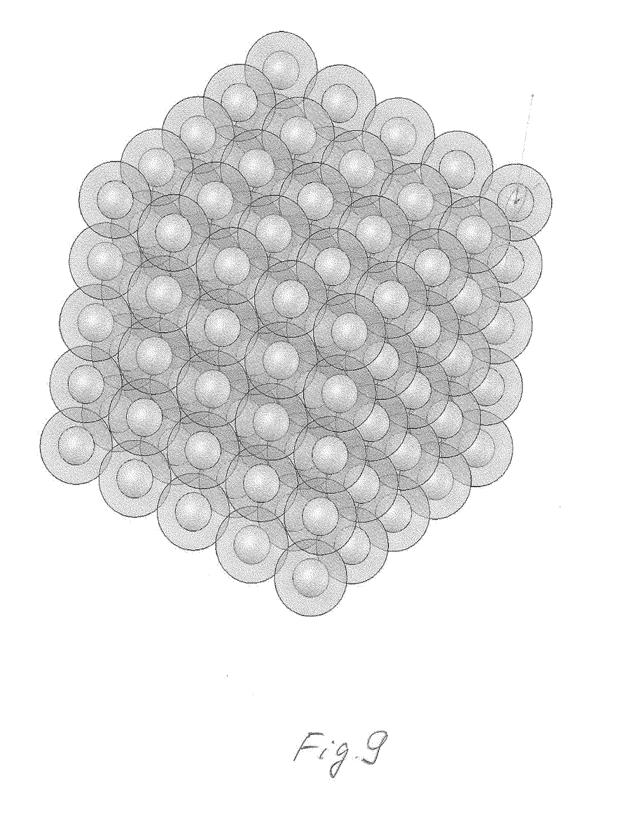

FIG. 7 shows geometric correlation between capsules before calibration and the mold before calibration. FIG. 7A shows the following, with the following reference numerals identify the following parts:
701—mold's side wall;
702—mold's side wall;
703—capsule shell; and
704—capsule core.

FIG. 7B shows the following, with the following reference numerals identify the following parts:
705—external diameter of the capsule's core substantially matching the diameter of the internal spherical cavity in the capsule shell;
706—external diameter of the capsule substantially matching the external diameter of the capsule shell;
707—distance between capsule centers substantially equal to the external diameter of the capsule sphere, at least in relation to two coordinate points in one plane; and
708—distance between mold walls substantially equal to the external diameter of the capsule multiplied by the number of capsules in the void between two opposite walls.

FIG. 7C shows the following, with the following reference numerals identify the following parts:
709—height of the capsule layer after calibration, within the limits of one layer;
710—shape of the capsule shell after calibration;
711—the duct inside which there is no metal from the plastically deformed capsule shell;
712—metal of the shell which, during calibration, moves toward mold wall;
713—metal of the shell which, during calibration, moves toward the inside of the open cavity between capsules; and
714—the size of the capsule equal by width to the diameter of the capsule before calibration.

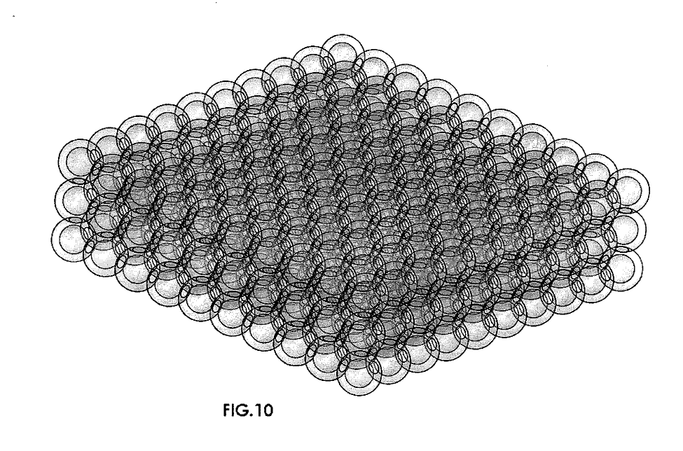

FIG. 8 provides an additional view of the composite material of FIG. 1. FIGS. 9-10 provide additional views of the plate of composite material of FIG. 4.

As disclosed herein, one or more objectives for composite materials according to some implementations of the invention include:
a. increasing the performance of electronic devices in which the proposed materials are to be used;
b. reducing the size of electronic devices in which the proposed materials are to be used;
c. increasing the level of reliability of electronic devices in which the proposed materials are to be used;
d. extending the lifetime of the electronic devices in which it is planned to use the proposed materials; and
e. increasing the general effectiveness of the electronic devices in which the proposed materials are to be used.

Composite materials according to some implementations can improve operating conditions and performance of high energy consuming and generating electronic devices; making it possible to create a new generation of electronic devices much less dependent on thermal characteristics, which is particularly desirable for powerful pulse equipment with power at the pulse peak exceeding the device's nominal power.

Additional capabilities obtained from composite materials according to some implementations include one or more of the following:
creating device bodies from the same material, with a homogeneous monotonic structure;
producing bodies and bearing parts of electronic devices in the form of a electrically conductive sponge system, able, in case of a sudden current peak pulses or sudden temperature peak pulses, to dissipate or accumulate excess portion of the suddenly occurring power; and
the ability to combine current and heat conducting functions in the same design element.

Below are listed other factors (singly, together, or in combination with one or more other factors) which may be employed to improve the effectiveness of the composite material:
the structure of the multi-layer (multi-level) capsule;
the geometrical form of the multi-layer (multi-level) capsule—sphere;
the alteration of the layers (levels) in the spherical capsule;
the order and the geometry of the location of spherical capsules in the object's three-dimensional structure;
object's technological manufacturing principle;
adding to the manufacturing process—operations involved in calibrating the object's geometrical shape, after first molding;
carrying out calibration operation in the three-dimensional coordinate system;
carrying out calibration operation when the material of the external layer (shell) of the capsule is close to or equivalent to cold-drawn state;
during calibration, removing substantially all cavities not filled with electrically conductive material from the object's three-dimensional space;
forming a pseudo sponge structure within the three-dimensional space of the object, where the functions of separating points in the structure are performed by less ductile materials from among those which are used in the capsule's composite;
using the object's sponge structure to dissipate heat and current around the entire volume;
using the object's pseudo sponge structure to absorb (consume) excess energy which is generated during the object's operation in pulse mode;
using the cold-drawn state to remove internal stresses in the material and size calibration in three coordinate systems simultaneously;
combining materials in the hierarchy of the capsule's spherically shaped hierarchy so that every subsequent layer is made out of harder and more ductile material;
combining materials in the hierarchy of the core and capsule's spherically shaped shells so that the core is made out of material which is the hardest of all materials used to produce the capsule;
preserving the sphere's hard core without deformations and a maximum level of plastic deformation of plastic materials of the capsule sphere's peripheral layers as primary principle of calibration;
using high specific pressure in an enclosed three-dimensional space to perform calibration;
applying the principle of uniform pressure distribution along all coordinates (axes) of the enclosed three-dimensional space; and
selecting the thickness of layers subject to plastic deformation so that the minimum thickness of the layer is bigger or equal to the capsule's core diameter.

Composite materials according to some implementations may realize one or more of the following advantages:
a super heat conducting, super electricity conducting, pseudo sponge composite three-dimensional structure.

The structure may realize one or more of the following advantages:
exceptionally high heat distribution;
exceptionally high current consumption;
low electrical resistance;
low thermal resistance;
small current level losses when it passes through the structure;
maximum speed with which pulse signals pass, with minimum energy losses; and
maximum absorption of energy pulses, which occur frequently and are short in duration, commensurate with the frequency of the pulses, and at pulse peak, maximum energy saturation is at least twice the nominal level.

One or more of the following advantages may also be realized in some implementations:
materials and nanospheres used as capsule core are produced serially on the basis of several identical technological processes and which can be obtained, if needed;
technological processes used to apply or build layers around the core (shells) are known and have been previously tested; and
three-dimensional calibration technological processes are used in the cold pressing technique, in the production of molds, matrices, etc.

It will be appreciated by those skilled in the art that various omissions, additions and modifications may be made to the methods and structures described above without departing from the scope of the invention. All such modifications and changes are intended to fall within the scope of the invention, as defined by the appended claims.

What is claimed is:

1. A composite material comprising:
a three-dimensional structure, wherein adjoining elements have differing physical properties;
a collection of molded together multilayered capsules, wherein external layers are transformed into a three-dimensional pseudo-porous form through plastic deformation, the pores of the shape containing capsule cores made from a material which is harder than the external layers of the material.

2. The composite material of claim 1, further comprising contact between the external surfaces of capsule shells in the three-dimensional pseudo porous form, the contact being full contact across mating faces making the blank from the composite material acquire pseudo-porous structure wherein capsule cores are uniformly distributed around the entire volume of ductile electrically conductive material.

3. The composite material of claim 1, further comprising contact between external surfaces of capsule shells in three-dimensional pseudo-porous form, the contact being full contact along mating faces, making the blank from the composite material acquire the pseudo-porous structure wherein capsule cores are uniformly distributed around the entire volume of ductile electrically conductive material, the cores made of diamond.

4. The composite material of claim 1, further comprising capsule cores, the capsules having a geometric shape of a sphere and even required dimensions, and their shells having a thickness commensurate with and proportional to the diameter of the sphere.

5. The composite material in claim 1, further comprising capsule cores and its shell made of constructive materials having differing physical, chemical and processing characteristics.

6. The composite material of claim 1, further comprising contact between the external surfaces of capsule shells in the three-dimensional pseudo porous form, the contact being full contact across mating faces making the blank from the composite material acquire pseudo-sponge wherein capsule cores are uniformly distributed around the entire volume of ductile electrically conductive material, the cores made of semi-conductor material.

7. The composite material of claim 1, further comprising contact between the external surfaces of capsule shells in the three-dimensional pseudo porous form, the contact being full contact across mating faces making the blank from the composite material acquire pseudo-sponge wherein capsule cores are uniformly distributed around the entire volume of ductile electrically conductive material, the cores made of ceramics.

8. The composite material of claim 1, further comprising contact between the external surfaces of capsule shells in the three-dimensional pseudo porous form, the contact being full contact across mating faces making the blank from the composite material acquire pseudo-sponge wherein capsule cores are uniformly distributed around the entire volume of ductile electrically conductive material, the cores made of hard alloy.

9. The composite material of claim 1, further comprising contact between the external surfaces of capsule shells in the three-dimensional pseudo porous form, the contact being full contact across mating faces making the blank from the composite material acquire pseudo-sponge wherein capsule cores are uniformly distributed around the entire volume of ductile electrically conductive material, the cores made of metal-ceramic.

10. The composite material of claim 1, further comprising contact between the external surfaces of capsule shells in the three-dimensional pseudo porous form, the contact being full contact across mating faces making the blank from the composite material acquire pseudo-sponge wherein capsule cores are uniformly distributed around the entire volume of ductile electrically conductive material, the cores made of heat-treated metal.

11. The composite material in claim 1, further comprising capsule cores and its shells having differing levels of ductility and at least the ductility of the shell under high pressure transforms into cold-drawn mode, and its fluidity at temperature below the melting temperature of the metal from which it was produced.

12. The composite material in claim 1, further comprising cores of multi-layered capsules made of high heaviness construction material and having a high thermal conductivity coefficient, and shells made from a metal with a high coefficient of ductility, thermal conductivity and electrical conductivity.

13. The composite material of claim 12, wherein the cores are formed of diamond and the shells are formed of copper.

14. The composite material in claim 1, further including, in case multi-layered capsules forming the composite material have more than two layers, wherein the first is the core of the capsule, the hardness of every subsequent layer in relation to the previous one decrease, whereas the plasticity increases.

15. The composite material in claim 1, further comprising cores of multi-layered capsules made from dielectric material of high hardness and high thermal conductivity coefficient.

16. The composite material in claim 15, wherein the cores are formed of a diamond.

17. The composite material in claim 1, further comprising shells of multi-layered capsules made from a ductile material with high electrical conductivity.

18. The composite material in claim 17, wherein the capsules are formed copper.

19. A method for producing pseudo sponge or pseudo porous composite material, comprising:
providing a collection of nano-capsules bound together into a three-dimensional structure; and
subjecting the structure to a plastic calibrating volume deformation in cold-drawn state for nano-capsule ductile shell material.

20. A system for producing a composite material formed from a collection of molded spherical multi-layered capsules, in two successive steps, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the volume wherein the level of specific pressure brings the capsules' plastic shell material to cold-drawn state and transforms the contact between the spheres from point contact into full contact along mating faces.

21. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure with capsule cores uniformly distributed around the entire volume of ductile electricity conductive material.

22. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of diamond.

23. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of ceramic.

24. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of semi-conductor.

25. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of metal-ceramic.

26. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of heat-treated metal.

27. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of hard alloy.

28. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of tungsten carbide.

29. The system of claim 20, formed from molded collection of spherical multi-layer capsules, in two successive stages, wherein the first involves contacting capsule spheres with external spherical surface, the contact being point contact, and the second step involves placing the blank after the first step in the three-dimensional enclosed volume geometrically equivalent to the design form of the object, and subjecting the blank in this volume to high pressure spreading along all the axes and coordinates of the given volume wherein the level of specific pressure brings the capsules' plastic shell material to cold-drawn state and transforms the contact between the spheres from point contact into full contact along mating faces making the slug acquire pseudo porous structure wherein capsule cores are uniformly distributed around the volume of ductile electricity conductive material, the cores made of titanium carbide.

30. A system producing a composite material having simultaneously thermally conductive and electrically conductive properties, or dielectric and electrically conductive properties, including the production of capsule spherical cores, coating the capsules with material, at least one external shell, placing a pre-determined number of capsules into a mold with linear dimensions of the matrix being a multiple of the dimensions of the capsule, applying high pressure to the capsule until cold-drawn and fluidity effect appears in the metal of capsule shells, and holding and calibrating the size dimensions of object made from the composite material.

31. The system of claim 30, having simultaneously thermally conductive and electrically conductive properties, or dielectric and electrically conductive properties, or thermally dissipative and electrically dissipative properties, including the production of capsule spherical cores, coating the capsules with material, at least one external shell, placing a pre-determined number of capsules into a mold with linear dimensions of the matrix being a multiple of the dimensions of the capsule, applying high pressure to the capsule until fluidity effect appears in the metal of capsule shells, holding and calibrating the size dimensions of object made from the composite material.

32. The system of claim 30, having simultaneously thermally, electrically and thermally dissipative properties, or dielectric; electrically conductive electrically dissipative properties, or simultaneously thermally conductive, electrically conductive, thermally dissipative and electrically dissipative properties, including the production of capsule spherical cores, coating the capsules with material, at least one external shell, placing a pre-determined number of capsules into a mold with linear dimensions of the matrix being a multiple of the dimensions of the capsule, applying high pressure to the capsule until fluidity effect appears in the metal of capsule shells, and holding and calibrating the size dimensions of object made from the composite material.

33. A device for forming a composite material from a collection of multi-layered capsules, the device comprising a matrix replicating the shape of the final object from the composite material, the matrix having the size a multiple of the size of the capsules before the start of the process of plastic deformation and punch, having a cross-section geometrically correlated with the cross section of the matrix, the geometric correlation changing as a function of the properties of the ductile material of capsule shells.
